(19) United States
(12) Patent Application Publication
(10) Pub. No.: US 2026/0025948 A1
(43) Pub. Date: Jan. 22, 2026

(54) COOLING SYSTEM AND METHOD OF COOLING COOLING SYSTEM

(71) Applicant: Fujitsu Limited, Kawasaki-shi (JP)

(72) Inventor: Kouichi KURAMITSU, Tokyo (JP)

(73) Assignee: Fujitsu Limited, Kawasaki-shi (JP)

(21) Appl. No.: 19/229,552

(22) Filed: Jun. 5, 2025

(30) Foreign Application Priority Data
Jul. 17, 2024 (JP) 2024-114233

(51) Int. Cl. H05K 7/20

(52) U.S. Cl. CPC H05K 7/20263; H05K 7/20272

(57) ABSTRACT

A cooling system includes a liquid-cooling target component provided in a casing, an air-cooling target component provided in the casing, a first heat exchanger that is provided outside the casing and cools a coolant discharged from the liquid-cooling target component, a pump that is provided outside the casing and delivers the coolant cooled by the first heat exchanger to the liquid-cooling target component, and a second heat exchanger that is provided in the casing, introduces a cooling air for cooling the air-cooling target component and the coolant delivered by the pump and before flowing through the liquid-cooling target component, and performs heat exchange between the cooling air and the coolant, wherein the cooling air is discharged outside the casing after passing through the second heat exchanger.

### CROSS-REFERENCE TO RELATED APPLICATION

This application is based upon and claims the benefit of priority of Japanese Patent Application No. 2024-114233 filed on Jul. 17, 2024, the entire contents of which are incorporated herein by reference.

### FIELD

A certain aspect of the present embodiments relates to a cooling system and a method of cooling a cooling system.

### BACKGROUND

A feat-generating component such as an electronic component may cause deterioration of characteristics and a reduction in life, and the like due to a temperature rise. For this reason, the heat-generating component is cooled. For example, there has been known a cooling system for cooling a liquid-cooling target component and air-cooling target component which are provided in one casing (for example, Patent Document 1: U.S. Laid-Open Patent Publication No. 2023/0023542, and Patent Document 2: Japanese Laid-Open Patent Publication No. 2023-84244).

### SUMMARY

According to an aspect of the present disclosure, there is provided a cooling system including: a liquid-cooling target component provided in a casing; an air-cooling target component provided in the casing; a first heat exchanger that is provided outside the casing and cools a coolant discharged from the liquid-cooling target component; a pump that is provided outside the casing and delivers the coolant cooled by the first heat exchanger to the liquid-cooling target component; and a second heat exchanger that is provided in the casing, introduces a cooling air for cooling the air-cooling target component and the coolant delivered by the pump and before flowing through the liquid-cooling target component, and performs heat exchange between the cooling air and the coolant; wherein the cooling air is discharged outside the casing after passing through the second heat exchanger.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF THE DRAWINGS

FIG. 1A is a plan view of a cooling system according to a first embodiment.

FIG. 1B is a side view of a casing viewed from a −Y direction of FIG. 1A.

FIG. 2A is a diagram illustrating a heat exchanger according to a first embodiment.

FIG. 2B is a diagram illustrating a cooling water circulating device according to the first embodiment.

FIG. 3 is a diagram illustrating an overall view of an open-loop type cooling system.

FIG. 4A is a plan view of a closed-loop type cooling system.

FIG. 4B is a side view of the casing viewed from the −Y direction of FIG. 4A.

FIG. 5A is a plan view of a cooling system according to a comparative example.

FIG. 5B is a side view of the casing viewed from a −Y direction in FIG. 5A.

FIG. 6 is a diagram illustrating the flow of a coolant in a second embodiment.

### DETAILED DESCRIPTION

In order to cool a liquid-cooling target component provided in a casing, a configuration in which a coolant is delivered to the liquid-cooling target component by a heat exchanger and a pump provided outside the casing is conceivable. In this case, if an air-cooling target component is provided in the casing, cooling air for cooling the air-cooling target component may be discharged outside the casing in a state of high temperature. When the high-temperature cooling air is discharged to the outside of the casing, a temperature in a room in which the casing is provided rises, and a load on an air conditioner that adjusts the temperature in the room to an appropriate temperature may increase.

In one aspect, it is an object of the present disclosure to suppress an increase in temperature of the cooling air discharged to the outside of the casing.

Hereinafter, embodiments of the present disclosure will be described with reference to the drawings.

### First Embodiment

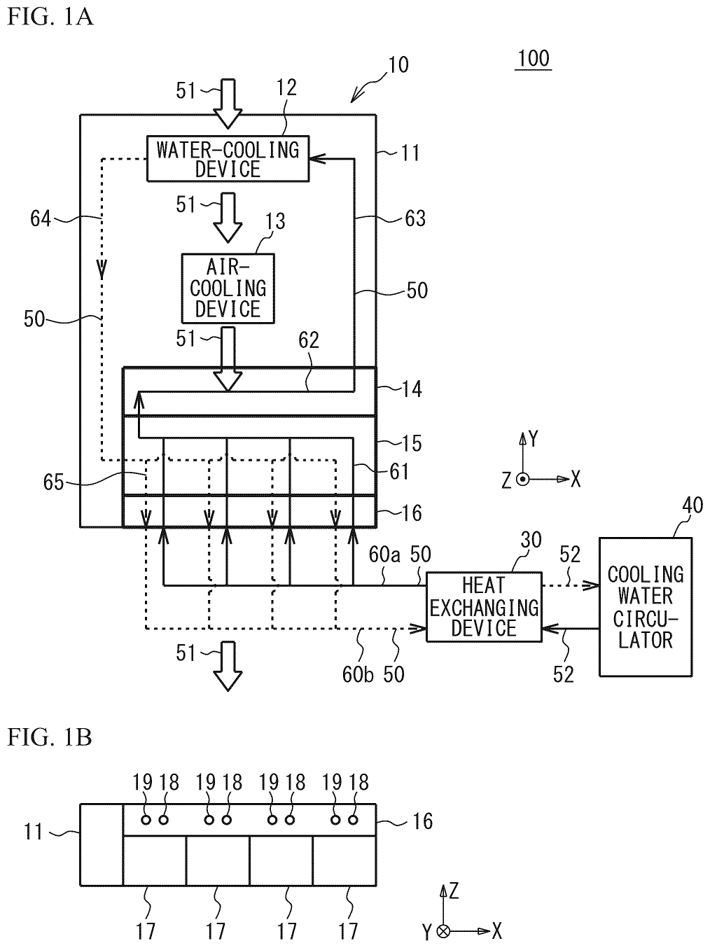

FIG. 1A is a plan view of a cooling system 100 according to a first embodiment, and FIG. 1B is a side view of a casing 11 seen from the −Y direction in FIG. 1A. In FIG. 1A, a path of a coolant 50 delivered from a heat exchanging device 30 to a water-cooling device 12 is indicated by solid line arrows. A path of the coolant 50 that has cooled the water-cooling device 12 from the water-cooling device 12 to the heat exchanging device 30 is indicated by dotted arrows.

As illustrated in FIGS. 1A and 1B, the cooling system 100 includes a device unit 10, the heat exchanging device 30, and a cooling water circulator 40. The device unit 10 is provided with the casing 11, the water-cooling device 12 (liquid-cooling target component), an air-cooling device 13 (air-cooling target component), a radiator 14 (second heat exchanger), a manifold 15, a connector 16, and one or more fans 17. The heat exchanging device 30 and the cooling water circulator 40 are provided outside the casing 11.

The water-cooling device 12 is a heat-generating component such as an electronic component that is cooled by the flow of the coolant 50 delivered from the heat exchanging device 30. The water-cooling device 12 is, for example, an optical module such as a QSFP (Quad Small Form-Factor Pluggable) or a high-power processor such as a DSP (Digital Signal Processor). The coolant 50 is, for example, cooling water, but may be other liquid.

The air-cooling device 13 is a heat-generating component such as an electronic component that is cooled by cooling air 51 generated by driving the fan 17. The air-cooling device 13 is, for example, a low-power optical device or a low-power integrated circuit such as an FPGA (Field Programmable Gate Array). Therefore, the air-cooling device 13 generates less heat than the water-cooling device 12.

The reason why the water-cooling device 12 and the air-cooling device 13 are provided in the casing 11 is as follows. If all the heat generating components in the casing 11 are water-cooling, the water-cooling structure becomes complicated and large. On the other hand, if all the heat generating components in the casing 11 are air-cooling, a heat sink for cooling a high-power heat generating component increases in size. Therefore, in order to increase the size of the device and to reduce the cost, the water-cooling device 12 and the air-cooling device 13 are used together.

The heat exchanging device 30 delivers the coolant 50 for cooling the water-cooling device 12, and draws in the coolant 50 after passing through the water-cooling device 12 and cooling the water-cooling device 12. Thus, the coolant 50 circulates between the heat exchanging device 30 and the water-cooling device 12. The heat exchanging device 30 is, for example, a CDU (Coolant Distribution Unit). The heat exchanging device 30 cools the coolant 50 of a secondary side circulating between the heat exchanging device 30 and the water-cooling device 12 by cooling water 52 of a primary side delivered from the cooling water circulator 40 such as a chiller.

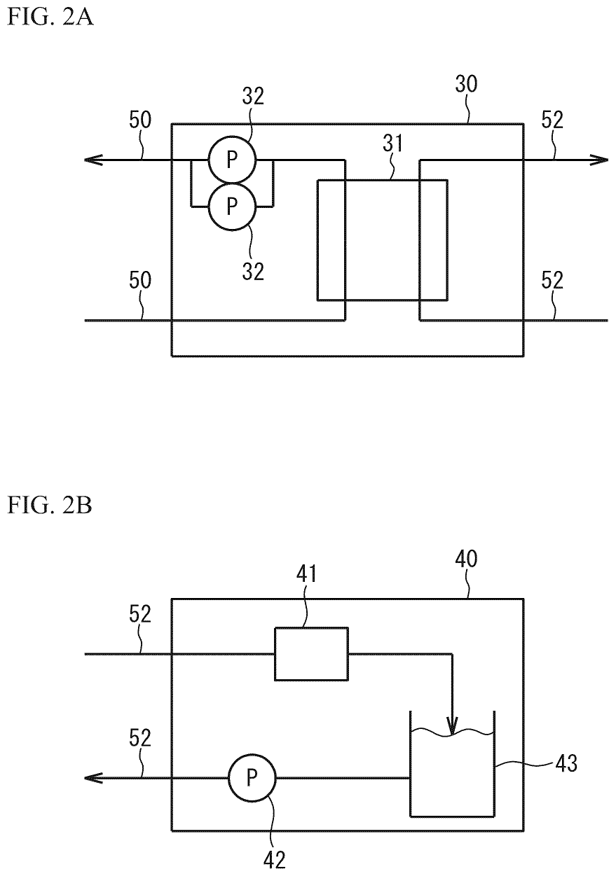

FIG. 2A is a diagram illustrating the heat exchanging device 30 according to the first embodiment, and FIG. 2B is a diagram illustrating the cooling water circulator 40 according to the first embodiment. As illustrated in FIG. 2A, the heat exchanging device 30 includes a heat exchanger 31 (first heat exchanger) and a pump 32. The heat exchanger 31 exchanges heat between the cooling water 52 of the primary side at, for example, 15° C. to 25° C. introduced from the cooling water circulator 40 and the coolant 50 of the secondary side introduced from the device unit 10, and cools the coolant 50 with the cooling water 52. The pump 32 delivers the coolant 50 cooled by the heat exchanger 31 toward the water-cooling device 12.

As illustrated in FIG. 2B, the cooling water circulator 40 includes a heat exchanger 41, a pump 42, and a water tank 43. The heat exchanger 41 is, for example, an air-cooling type, and cools the cooling water 52 circulated through the heat exchanging device 30 by exchanging heat with cooling air. The water tank 43 stores the cooling water 52 that has passed through the heat exchanger 41. The pump 42 delivers the cooling water 52 stored in the water tank 43 toward the heat exchanging device 30.

As illustrated in FIGS. 1A and 1B, the heat exchanging device 30 is connected to the connector 16 through pipes 60a and 60b. The connector 16 has, for example, four pairs of connection ports 18 and 19. The pipe 60a is connected to the heat exchanging device 30 by one pipe, and branches into four pipes between the heat exchanging device 30 and the connector 16. The four pipes are connected to the four connection ports 18 of the pair of connection ports 18 and 19 of the connector 16, respectively. The pipe 60b is also connected to the heat exchanging device 30 by one pipe, and branches into four pipes between the heat exchanging device 30 and the connector 16. The four pipes are connected to the four connection ports 19 of the connector 16, respectively. The heat exchanging device 30 delivers the coolant 50 to the pipe 60a. The heat exchanging device 30 draws in the coolant 50 from the pipe 60b. The pair of connection ports 18 and 19 is not limited to the case where four pairs are provided, only one pair may be provided, or a plurality of pairs other than the four pairs may be provided.

The connector 16 is connected to the manifold 15. The manifold 15 is connected to the radiator 14. The radiator 14 has a flow path 62. The manifold 15 has a flow path 61 and a flow path 65. One end of the flow path 61 of the manifold 15 is connected to the flow path 62 of the radiator 14, and the other end of the flow path 61 is branched into four and connected to the four connection ports 18 of the connector 16. Accordingly, the flow path 61 combines the coolants 50 introduced into the four connection ports 18 of the connector 16 and flowing in parallel with each other into one flow path 62 of the radiator 14. In this way, the coolant 50 delivered from the heat exchanging device 30 is introduced into the radiator 14 via the connector 16 and the manifold 15. A flow path 63 connecting the radiator 14 and the water-cooling device 12 is provided in the casing 11. Therefore, the coolant 50 having passed through the flow path 62 of the radiator 14 flows through the flow path 63 and is introduced into the water-cooling device 12.

The coolant 50 that has passed through the water-cooling device 12 and cooled the water-cooling device 12 is discharged to a flow path 64 provided in the casing 11. The flow path 64 is connected to one end of the flow path 65 of the manifold 15. The other end of the flow path 65 is branched into four and connected to the four connection ports 19 of the connector 16. Accordingly, the coolant 50 discharged from the water-cooling device 12 to the flow path 64 flows through the pipe 60b via the manifold 15 and the connection port 19 of the connector 16 and flows into the heat exchanging device 30.

The fan 17 is driven to generate the cooling air 51 flowing in the casing 11. The cooling air 51 flows to a heat sink that is in contact with the air-cooling device 13. Accordingly, the air-cooling device 13 is cooled by the cooling air 51. The cooling air 51 is introduced into the radiator 14 disposed at a later stage in the flow of the cooling air 51 than the air-cooling device 13. The cooling air 51 passes through the radiator 14 and then is discharged to the outside of the casing 11 through the fan 17. No cooling target component is provided between the fan 17 and the radiator 14, and at a later stage in the flow of the cooling air 51 than the fan 17. The cooling air 51 is directly discharged from the fan 17 to the outside of the casing 11.

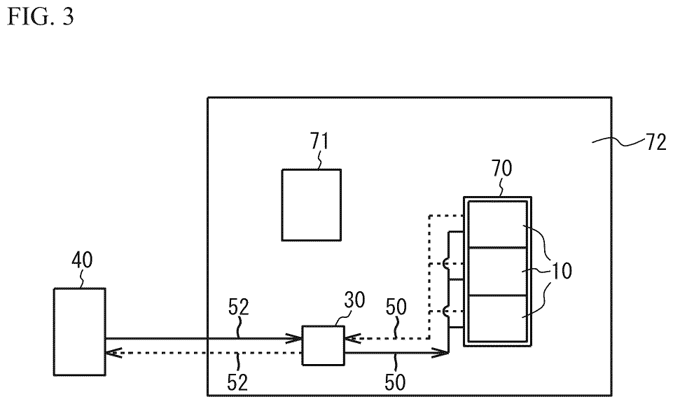

The cooling system in which the heat exchanging device 30 and the cooling water circulator 40 are provided outside the casing 11 in the first embodiment is called an open-loop type cooling system. FIG. 3 is a diagram illustrating an overall view of the open-loop type cooling system. As illustrated in FIG. 3, a rack 70 in which a plurality of device units 10 are accommodated, the heat exchanging device 30, and an air conditioner 71 are provided indoors. The cooling water circulator 40 is provided outdoors. The air conditioner 71 is provided to adjust the temperature of a room 72 in which the rack 70 is installed to an appropriate temperature. Although the heat exchanging device 30 is provided in the room 72 without being accommodated in the rack 70, the heat exchanging device 30 may be accommodated in the rack 70.

In the open-loop type cooling system, since the cooling water circulator 40 is provided outdoors, the heat received by the coolant 50 when cooling the water-cooling device 12 is discharged to the outdoors from the cooling water circulator 40. Therefore, the temperature rise in the room 72 where the device unit 10 is installed is suppressed, which has an advantage that the load on the air conditioner 71 is suppressed.

In addition to the open-loop type cooling system, a closed-loop type cooling system is known. The closed-loop type cooling system is a system in which a pump is disposed in a casing provided with a water-cooling device or the like, and a coolant for cooling the water-cooling device is circulated by the pump.

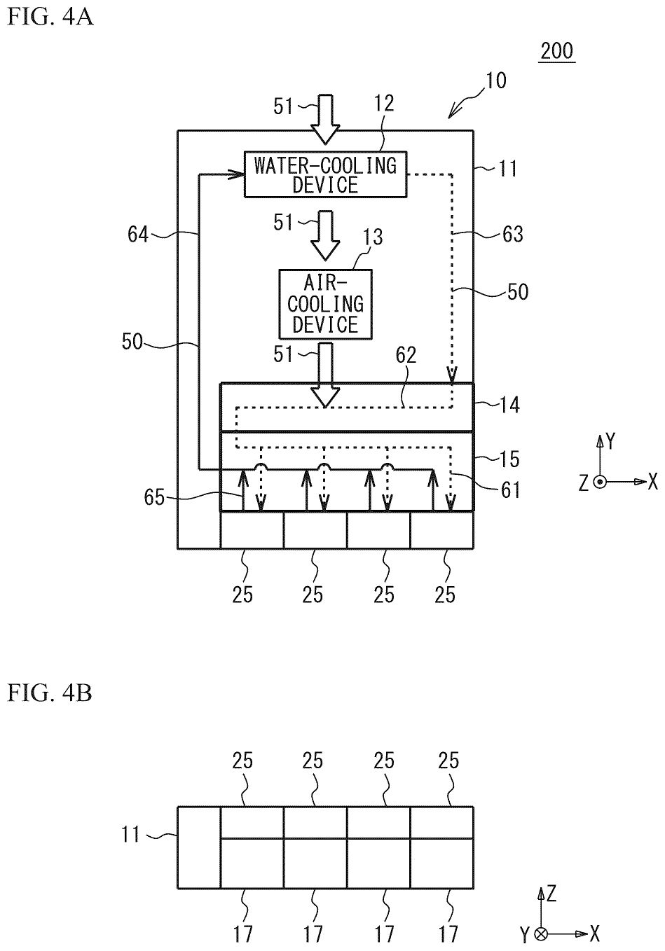

FIG. 4A is a plan view of a closed-loop type cooling system 200, and FIG. 4B is a side view of the casing 11 seen from a −Y direction in FIG. 4A. In FIG. 4A, a path of the coolant 50 delivered from pumps 25 to the water-cooling device 12 is indicated by solid line arrows. A path of the coolant 50 that has cooled the water-cooling device 12 from the water-cooling device 12 to the pumps 25 is indicated by dotted line arrows.

As illustrated in FIGS. 4A and 4B, in the closed-loop type cooling system, the heat exchanging device 30 and the cooling water circulator 40 are not provided outside the casing 11. One or a plurality of pumps 25 are provided in the casing 11 in place of the connector 16. The pumps 25 deliver the coolant 50 to be introduced into the water-cooling device 12.

The coolant 50 delivered by the pump 25 flows through the flow path 65 of the manifold 15 and the flow path 64 in the casing 11, and is introduced into the water-cooling device 12. In this way, the coolant 50 is introduced into the water-cooling device 12 without passing through the radiator 14. The coolant 50 that has passed through the water-cooling device 12 and cooled the water-cooling device 12 flows through the flow path 63 in the casing 11 and flows into the flow path 62 of the radiator 14. The radiator 14 exchanges heat between the coolant 50 discharged from the water-cooling device 12 and the cooling air 51. Since the temperature of the coolant 50 that has cooled the water-cooling device 12 is higher than that of the cooling air 51, the coolant 50 is cooled by the cooling air 51. The coolant 50 cooled by the radiator 14 flows through the flow path 61 of the manifold 15 and is sucked into the pump 25. The other components are the same as those of the first embodiment, and therefore, the description thereof is omitted.

In the closed-loop type cooling system, the coolant 50 whose temperature has been increased by cooling the water-cooling device 12 is cooled by the cooling air 51 in the radiator 14 and then flows into the pump 25. This is because when the coolant 50 having a high temperature flows into the pump 25, the pump 25 is likely to fail, and the life of the pump 25 is shortened.

### Comparative Example

A comparative example in which the closed-loop type cooling system illustrated in FIGS. 4A and 4B is replaced with an open-loop type cooling system will be described.

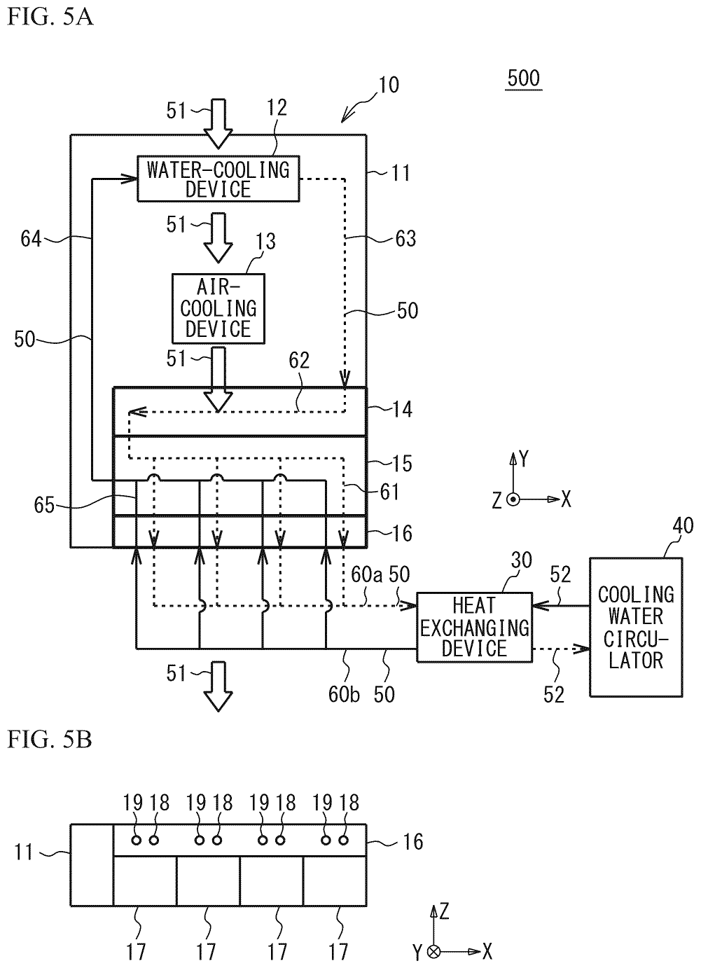

FIG. 5A is a plan view of a cooling system 500 according to a comparative example, and FIG. 5B is a side view of the casing 11 seen from the −Y direction in FIG. 5A. In FIG. 5A, as in FIG. 1A, a path of the coolant 50 delivered from the heat exchanging device 30 to the water-cooling device 12 is indicated by solid line arrows. A path of the coolant 50 that has cooled the water-cooling device 12 from the water-cooling device 12 to the heat exchanging device 30 is indicated by dotted line arrows.

As illustrated in FIGS. 5A and 5B, the pumps 25 of the closed-loop type cooling system illustrated in FIGS. 4A and 4B are replaced with the connector 16. The pipes 60a and 60b connected to the heat exchanging device 30 are connected to the connection ports 18 and 19 of the connector 16. Thus, the closed-loop type cooling system can be changed to the open-loop type cooling system.

In the comparative example, even when the closed-loop type is changed to the open-loop type, the direction of flow of the coolant 50 in the open-loop type is the same as that in the closed-loop type. That is, in the comparative example, the coolant 50 delivered from the heat exchanging device 30 flows into the flow path 65 of the manifold 15 from the connection port 19 of the connector 16. The coolant 50 is introduced into the water-cooling device 12 through the flow path 65 and the flow path 64. The coolant 50 having passed through the water-cooling device 12 to cool the water-cooling device 12 flows through the flow path 63 and is introduced into the flow path 62 of the radiator 14. The coolant 50 having passed through the flow path 62 flows through the flow path 61 of the manifold 15, and then flows through the pipe 60a from the connection port 18 of the connector 16 to be sucked into the heat exchanging device 30.

In the comparative example, the coolant 50 that has passed through the water-cooling device 12 and cooled the water-cooling device 12 is introduced into the flow path 62 of the radiator 14, and therefore the temperature of the coolant 50 in the radiator 14 is higher than the temperature of the cooling air 51. For example, even when the cooling air 51 whose temperature has increased by cooling the air-cooling device 13 passes through the radiator 14, the temperature of the coolant 50 in the radiator 14 is higher than that of the cooling air 51 because the water-cooling device 12 generates a larger amount of heat than the air-cooling device 13. When the coolant 50 and the cooling air 51 exchange heat in the radiator 14, the temperature of the cooling air 51 is increased by the coolant 50. Accordingly, the cooling air 51 having a high temperature is discharged to the outside of the casing 11.

As described with reference to FIG. 3, in the open-loop type cooling system, since the cooling water circulator 40 is provided outdoors, it is expected that the temperature rise in the room 72 is suppressed and the load on the air conditioner 71 is suppressed. However, in the comparative example, the temperature of the cooling air 51 is increased by heat exchange with the coolant 50 in the radiator 14, and the cooling air 51 having a high temperature is discharged into the room 72. For this reason, the temperature of the room 72 may rise, and the load on the air conditioner 71 may increase.

Therefore, when the closed-loop type cooling system illustrated in FIG. 4A is changed to the open-loop type cooling system, the direction of flow of the coolant 50 is reversed in the first embodiment as illustrated in FIG. 1A. That is, the following is performed when the closed-loop type in which the coolant 50 is circulated by the pump 25 (first pump) in the casing 11 is changed to the open-loop type in which the coolant 50 is circulated by the heat exchanging device 30 (second pump) outside the casing 11. A first setting (FIG. 4A) in which the coolant 50 discharged from the water-cooling device 12 is introduced into the radiator 14 is switched to a second setting (FIG. 1A) in which the coolant 50 delivered from the heat exchanging device 30 is introduced into the radiator 14 before flowing through the water-cooling device 12.

As a result, the cooling air 51 and the coolant 50 delivered from the heat exchanging device 30 and before flowing through the water-cooling device 12 are introduced into the radiator 14. Since the temperature of the coolant 50 before flowing through the water-cooling device 12 is low, the cooling air 51 is cooled by the coolant 50 by heat exchange between the cooling air 51 and the coolant 50 in the radiator 14. Since the cooling air 51 is discharged to the outside of the casing 11 after passing through the radiator 14, the discharge of the cooling air 51 having a high temperature from the casing 11 to the outside can be suppressed. Therefore, the temperature rise in the room 72 is suppressed, and the load on the air conditioner 71 is suppressed from increasing. Further, the cooling system can be changed to the open-loop type cooling system that can obtain the advantage of suppressing the temperature rise in the room 72 by making only a minimum change and/or modification to the closed-loop type cooling system. Further, since the components can be shared between the closed-loop type cooling system and the open-loop type cooling system, the cost can be reduced.

In the first embodiment, as illustrated in FIGS. 1A and 1B, the cooling air 51 passes through the radiator 14 and is discharged to the outside of the casing 11 without getting in contact with the cooling target component. This can prevent the cooling air 51 having a high temperature from being discharged from the casing 11 to the outside.

In the first embodiment, as illustrated in FIGS. 1A and 1B, the fan 17 and the radiator 14 are provided adjacent to each other without interposing any cooling target component therebetween. The cooling air 51 is directly discharged from the fan 17 to the outside of the casing 11. This can prevent the cooling air 51 having a high temperature from being discharged from the casing 11 to the outside.

In the first embodiment, as illustrated in FIGS. 1A and 1B, the casing 11 is provided with the connector 16 having the plurality of connection ports 18 to which the pipe 60a through which the coolant 50 flows is connected. The coolant 50 delivered from the heat exchanging device 30 is introduced into the plurality of connection ports 18 in parallel with each other through the pipe 60a. This makes it possible to increase the flow rate of the coolant 50 introduced into the water-cooling device 12, and to improve the cooling performance for the water-cooling device 12.

In the first embodiment, the manifold 15 is provided between the connector 16 and the radiator 14 as illustrated in FIG. 1A. The manifold 15 has the flow path 61 that merges the coolants 50 flowing in parallel with each other and introduced into the plurality of connection ports 18 of the connector 16 into one and that introduces the merged coolant 50 into the radiator 14. This makes it possible to provide the radiator 14 with only one flow path 62 through which the coolant 50 flows, which facilitates the design of the radiator 14. Further, since the length of the flow path 62 can be increased, the temperature of the cooling air 51 can be effectively decreased by the coolant 50 flowing through the flow path 62.

In the first embodiment, when the closed-loop type cooling system 200 illustrated in FIGS. 4A and 4B is changed to the open-loop type cooling system 100 illustrated in FIGS. 1A and 1B, the pumps 25 are replaced with the connector 16 to which the heat exchanging device 30 is connected. Thus, the closed-loop type cooling system 200 can be easily changed to the open-loop type cooling system 100 that can obtain the advantage of suppressing the temperature rise in the room 72.

In the first embodiment, the connector 16 illustrated in FIGS. 1A and 1B can be replaced with the pump 25 illustrated in FIGS. 4A and 4B. Thus, the open-loop type cooling system 100 illustrated in FIG. 1A can be replaced with the closed-loop type cooling system 200 illustrated in FIG. 4A.

In the first embodiment, the pipes 60a and 60b may be connected to the cooling water circulator 40 without providing the heat exchanging device 30. In this case, the heat exchanger 41 of the cooling water circulator 40 illustrated in FIG. 2B serves as a first heat exchanger that cools the coolant 50 discharged from the water-cooling device 12. The pump 42 serves as a pump (second pump) that delivers the coolant 50 cooled by the heat exchanger 41 to the water-cooling device 12.

### Second Embodiment

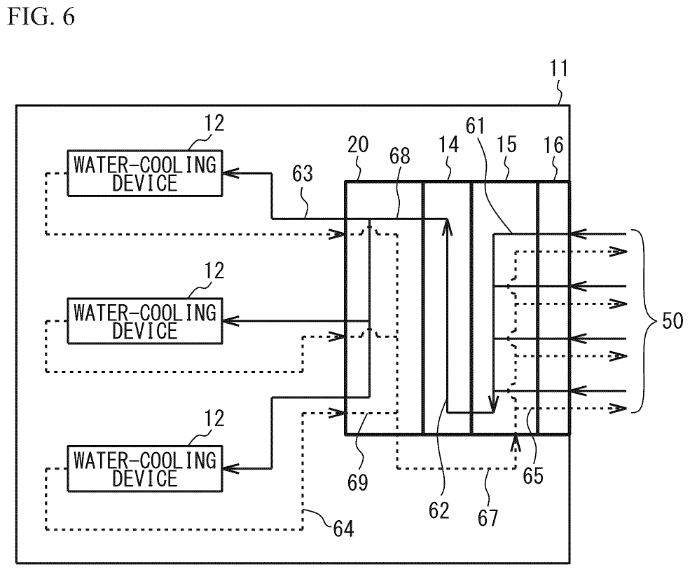

FIG. 6 is a diagram illustrating the flow of the coolant 50 in a second embodiment. As illustrated in FIG. 6, in the second embodiment, a plurality of water-cooling devices 12 are provided in the casing 11. A manifold 20 is provided between the radiator 14 and the water-cooling device 12. The manifold 20 has flow paths 68 and 69. One end of the flow path 68 is connected to the flow path 62 of the radiator 14, and the other end of the flow path 68 is branched into three and the branched flow paths are connected to the flow paths 63, respectively. As a result, the coolant 50 having passed through the flow path 62 of the radiator 14 is divided into a plurality of coolants 50 by the manifold 20, and the plurality of coolants 50 are introduced into a plurality of water-cooling devices 12 through the plurality of flow paths 63, respectively.

The coolants 50 that have passed through the plurality of water-cooling devices 12 and cooled the water-cooling devices 12 are discharged to the flow paths 64 connected to the plurality of water-cooling devices 12. The plurality of flow paths 64 are connected to the flow paths 69 of the manifold 20. The flow paths 69 are combined into one flow path and the one flow path is connected to one end of a flow path 67 in the casing 11. The other end of the flow path 67 is connected to the flow path 65 of the manifold 15. As a result, the coolants 50 discharged from the plurality of water-cooling devices 12 into the plurality of flow paths 64 are collected into one coolant 50 in the manifold 20 and then flows into the manifold 15. The other configurations of the second embodiment are the same as those of the first embodiment, and therefore the description thereof is omitted.

As in the second embodiment, the plurality of water-cooling devices 12 may be provided in the casing 11. In this case, it is preferable to provide the manifold 20 that distributes the coolant 50 that has passed through the radiator 14 to the plurality of water-cooling devices 12.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various change, substitutions, and alterations could be made hereto without departing from the spirit and scope of the invention.

What is claimed is:

1. A cooling system comprising:
a liquid-cooling target component provided in a casing;
an air-cooling target component provided in the casing;
a first heat exchanger that is provided outside the casing and cools a coolant discharged from the liquid-cooling target component;
a pump that is provided outside the casing and delivers the coolant cooled by the first heat exchanger to the liquid-cooling target component; and
a second heat exchanger that is provided in the casing, introduces a cooling air for cooling the air-cooling target component and the coolant delivered by the pump and before flowing through the liquid-cooling target component, and performs heat exchange between the cooling air and the coolant;
wherein the cooling air is discharged outside the casing after passing through the second heat exchanger.

2. The cooling system according to claim 1, wherein
the cooling air passes through the second heat exchanger and is discharged outside the casing without getting in contact with a cooling target component.

3. The cooling system according to claim 1, wherein
the cooling air gets in contact with a cooling target component before passing through the second heat exchanger.

4. The cooling system according to claim 1, further comprising
a fan that is provided in the casing and generates the cooling air,
wherein the fan and the second heat exchanger are provided adjacent to each other without interposing a cooling target component therebetween, and the cooling air is directly discharged from the fan to outside of the casing.

5. The cooling system according to claim 1, further comprising
a connector that is provided in the casing and has a plurality of connection ports connected to a pipe through which the coolant flows,
wherein the coolant delivered from the pump flows into the plurality of connection ports in parallel with each other through the pipe.

6. The cooling system according to claim 5, further comprising
a manifold that is provided between the connector and the second heat exchanger, and has a flow path that merges the coolant flowing in parallel with each other and flowing into the plurality of connection ports into one flow, the flow path flowing merged coolant into the second heat exchanger.

7. The cooling system according to claim 1, wherein
the casing is provided with a plurality of liquid-cooling target components, and
the cooling system further includes a manifold that distributes the coolant that has passed through the second heat exchanger to the plurality of the liquid-cooling target components.

8. A method of cooling a cooling system, the cooling system including, in a casing, a liquid-cooling target component, an air-cooling target component, a second heat exchanger that introduces a cooling air for cooling the air-cooling target component and a coolant for cooling the air-cooling target component, and performs heat exchange between the cooling air and the coolant, the cooling air being discharged outside the casing after passing through the second heat exchanger, the method of cooling the cooling system comprising:
when a configuration in which the coolant is circulated by a first pump provided in the casing is changed to a configuration in which the coolant cooled by a first heat exchanger provided outside the casing is circulated by a second pump provided outside the casing, switching from a first setting in which the coolant discharged from the liquid-cooling target component is introduced into the second heat exchanger to a second setting in which the coolant delivered by the second pump is introduced into the second heat exchanger before flowing through the liquid-cooling target component.

9. The method of cooling the cooling system according to claim 8, wherein
the switching from the first setting to the second setting is performed by replacing the first pump with a connector to which the second pump is connected.

10. The method of cooling the cooling system according to claim 9, wherein
the switching from the second setting to the first setting is performed by replacing the connector with the first pump.
